(19) United States
(12) Patent Application Publication
(10) Pub. No.: US 2011/0120526 A1
(43) Pub. Date: May 26, 2011

(54) Monolithic Low Concentration Photovoltaic Panel Based On Polymer Embedded Photovoltaic Cells And Crossed Compound Parabolic Concentrators

(75) Inventors: Zohar Haviv, Har-Hadar (IL); Mauricio De La Vega, Rehovot (IL)

(73) Assignee: IMPEL MICROCHIP LTD., Har-Adar (IL)

(21) Appl. No.: 12/994,328

(22) PCT Filed: May 26, 2009
(86) PCT No.: PCT/IL2009/000520

§ 371 Date: Feb. 3, 2011

(30) Foreign Application Priority Data
May 26, 2008 (IL) 191713
May 25, 2009 (IL) 198954

(51) Int. Cl. H01L 31/052; H01L 31/05; H01L 31/06; H01L 31/18

(52) U.S. Cl. 136/246; 136/255; 438/69; 257/E31.001

(57) ABSTRACT

A concentrating photovoltaic panel including an encapsulating polymer layer, an array of photovoltaic cells, a plurality of first interconnects and an optical layer, each of the photovoltaic cells is embedded within the encapsulating layer, the plurality of first interconnects is coupled with each of the photovoltaic cells and with the encapsulating layer, the plurality of first interconnects electrically interconnecting all the photovoltaic cells of the array there-between, the optical layer is coupled on top of the encapsulating layer and the array of photovoltaic cells, the optical layer concentrating light radiation onto the array of photovoltaic cells, at least one of the first interconnects remains exposed out of the protective layer.

### FIELD OF THE DISCLOSED TECHNIQUE

The disclosed technique relates to concentrating photovoltaic panels in general, and to a monolithic concentrating photovoltaic solar panel based on polymer embedded photovoltaic cells, interconnects, and crossed Compound Parabolic Concentrators (CPC), in particular.

### BACKGROUND OF THE DISCLOSED TECHNIQUE

In flat panel photovoltaic technologies (e.g., based on mono-crystalline silicon wafers, poly-crystalline silicon wafers, multi-junction cells and tandem cells), the cost of the photovoltaic material dictates a large portion of the total panel cost. For example, in case of mono-crystalline based solar panels, the cost of silicon wafers carries approximately 65% of the total panel cost.

Concentrating photovoltaic technologies are employed in order to reduce the photovoltaic material content of the solar panel, thereby, reducing its cost. Expensive photovoltaic materials are replaced by relatively cheap lenses and optical concentrators. The larger the optical concentration value of the system (i.e., the amount of light radiation energy focused onto a specific surface area), the lower will be the total active photovoltaic area of the system.

Reference is now made to FIG. 1, which is a schematic illustration of a concentrating photovoltaic device, generally referenced 10, constructed and operative as known in the art. Concentrating photovoltaic device 10 includes a photovoltaic cell 12, a substrate 14, a plurality of interconnects 16, a plurality of wires 18 and a lens 20. Photovoltaic cell 12 is positioned on top of substrate 14, approximately in the center thereof. Photovoltaic cell 12 can be any photovoltaic cell known in the art, such as a mono-crystalline silicon cell, a poly-crystalline silicon cell, a multi-junction cell, or a tandem cell. Photovoltaic cell 12 converts light radiation into electrical current. Substrate 14 functions as a structural base and as a heat sink.

Wires 18 transfer the generated electrical current from photovoltaic cell 12 to interconnects 16. Lens 20 is a concentrating lens, which concentrates light radiation toward photovoltaic cell 12. For example, lens 20 concentrates each of parallel beams 22A, 24A and 26A toward photovoltaic cell 12. Each of concentrated beams 22B, 24B and 26B corresponds to each of un-concentrated parallel beams 22A, 24A and 26A. The distance of between lens 20 and photovoltaic cell 12 is determined by the value of a depth of focus of concentrating photovoltaic device 10. The value of the depth of focus of concentrating photovoltaic device 10 is related to the concentration power and the design of lens 20, and of the size of photovoltaic cell 12.

In most concentrating photovoltaic panels that include an array of concentrating photovoltaic devices (e.g., photovoltaic device 10), each photovoltaic cell is assembled and interconnected individually. At high optical concentration values, the total active photovoltaic area required by the system is small, and hence small sized photovoltaic cells are employed. For example, in high optical concentration applications, photovoltaic cells with areas down to 4 millimeters square are employed.

A view angle is the angle of incoming light beams, which an optical element can receive (i.e., field of view). Low concentration photovoltaic devices operate at high view angles (i.e., large field of view), and thus do not require mechanical sun tracking devices. Optical concentrations of up to a factor of ten are employed in low concentration photovoltaic devices. In prior art systems, at low optical concentration values, the total active photovoltaic area required by the system is large, and hence small sized photovoltaic cells are rarely employed.

### SUMMARY OF THE PRESENT DISCLOSED TECHNIQUE

It is an object of the disclosed technique to provide a monolithic concentrating photovoltaic solar panel based on polymer embedded photovoltaic cells, interconnects, and crossed Compound Parabolic Concentrators and a method for the production thereof.

In accordance with an embodiment of the disclosed technique, there is thus provided a concentrating photovoltaic panel. The panel includes an encapsulating polymer layer, an array of photovoltaic cells, a plurality of first interconnects and an optical layer. Each of the photovoltaic cells is embedded within the encapsulating layer. The plurality of first interconnects is coupled with each of the photovoltaic cells and with the encapsulating layer. The plurality of first interconnects electrically interconnect all the photovoltaic cells of the array there between. The optical layer is coupled on top of the encapsulating layer and the array of photovoltaic cells. The optical layer concentrates light radiation onto the array of photovoltaic cells. At least one of the plurality of first interconnects remains exposed out of the protective layer.

In accordance with another embodiment of the disclosed technique, there is thus provided a method for producing a photovoltaic concentrating panel. The method includes the following procedures, forming a matrix layer, forming a first interconnecting layer, forming a protective layer and forming an optical layer. The procedure of forming a matrix layer is performed by embedding an array of photovoltaic cells within a polymer resin material. The procedure of forming a first interconnecting layer is performed by electrically coupling between terminals of the photovoltaic cells. The procedure of forming a protective layer includes forming at least one opening in the protective layer. The procedure of forming an optical layer is performed such that each of a plurality of parabolic concentrators is optically coupled with a respective one of the array of photovoltaic cells.

In accordance with a further embodiment of the disclosed technique, there is thus provided a photovoltaic cell. The photovoltaic cell includes an N type doped semiconductor layer, a P type doped semiconductor layer, a passivation layer and a high concentration doped layer. The P type layer is positioned on the top surface of the N type layer. The size of the surface area of the bottom surface of the N type layer is larger than that of the top surface of the P type layer. The passivation layer is positioned on the top surface of the P type layer. The passivation layer provides passivation protection to the photovoltaic cell. The high concentration doped layer covers all sides of the P type layer and of the N type layer. The doping concentration of the high concentration doped layer is larger than that of each of the P type layer and the N type layer by at least two orders of magnitude. The high concentration doped layer is tilted with respect to the normal to the top surface of the P type layer.

### BRIEF DESCRIPTION OF THE DRAWINGS

The disclosed technique will be understood and appreciated more fully from the following detailed description taken in conjunction with the drawings in which:

FIG. 1 is a schematic illustration of a concentrating photovoltaic device, constructed and operative as known in the art;

FIG. 2A is a schematic illustration of a top view of a chip-sized photovoltaic cell, constructed and operative in accordance with an embodiment of the disclosed technique;

FIG. 2B is a schematic illustration of a bottom view of the chip-sized photovoltaic cell of FIG. 2A;

FIG. 2C is a schematic illustration of a cross section view of the chip-sized photovoltaic cell of FIG. 2A;

FIG. 3A is a schematic illustration of a cross section of a concentrating photovoltaic panel, constructed and operative in accordance with another embodiment of, the disclosed technique;

FIG. 3B is a schematic illustration of the optical layer of FIG. 3A;

FIGS. 4A and 4B are schematic illustrations of a concentrating photovoltaic panel, constructed and operative in accordance with a further embodiment of the disclosed technique;

FIG. 5 is a schematic illustration of a cross section of a concentrating photovoltaic panel, constructed and operative in accordance with another embodiment of the disclosed technique;

FIG. 6A is a schematic illustration of a bottom view of a concentrating photovoltaic panel, constructed and operative in accordance with a further embodiment of the disclosed technique;

FIG. 6B is a schematic illustration of a top view of the photovoltaic panel of FIG. 6A;

FIG. 7A is a schematic illustration of a top view of a chip-sized photovoltaic cell, constructed and operative in accordance with another embodiment of the disclosed technique;

FIG. 7B is a cross section view of the photovoltaic cell of FIG. 7A;

FIG. 7C is a bottom view of the photovoltaic cell of FIG. 7A;

FIG. 8 is a schematic illustration of a cross section of a concentrating photovoltaic panel, constructed and operative in accordance with a further embodiment of the disclosed technique;

FIG. 9 is a schematic illustration of a bottom view of an interconnect of a photovoltaic cell, constructed and operative in accordance with another embodiment of the disclosed technique;

FIG. 10 is a schematic illustration of a bottom view of an interconnects platform of a photovoltaic panel, constructed and operative in accordance with a further embodiment of the disclosed technique;

FIG. 10B is an enlarged view of a segment of FIG. 10A;

FIG. 11 is a schematic illustration of a bottom view of an interconnects platform of a photovoltaic panel, constructed and operative in accordance with another embodiment of the disclosed technique; and

FIG. 12 is a schematic illustration of a block diagram of a method for constructing a concentrating photovoltaic panel, operative in accordance with a further embodiment of the disclosed technique.

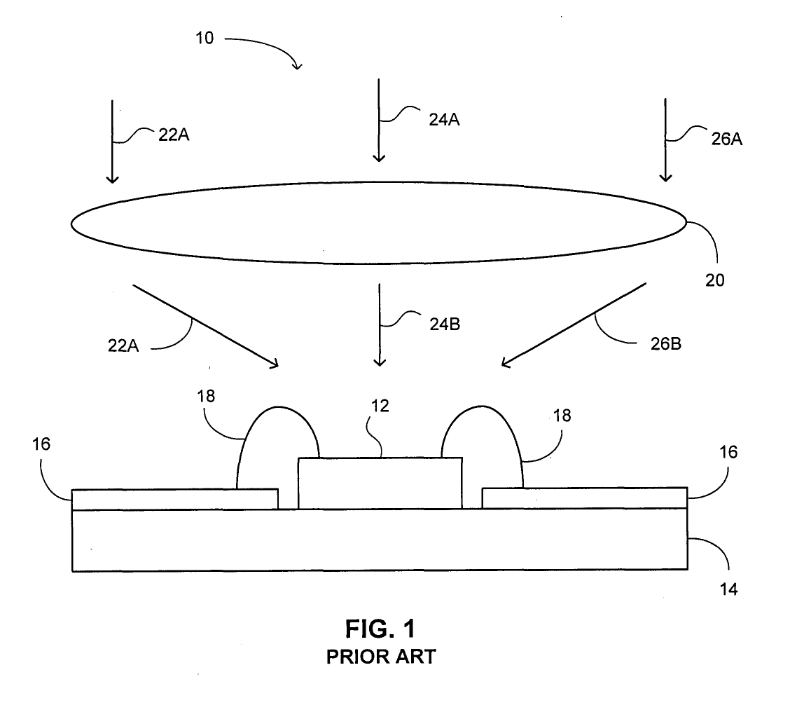

### DETAILED DESCRIPTION OF THE EMBODIMENTS

The disclosed technique overcomes the disadvantages of the prior art by providing a monolithic concentrated solar panel including a plurality of polymer embedded photovoltaic cells, a plurality of interconnects and a plurality of crossed compound parabolic concentrators.

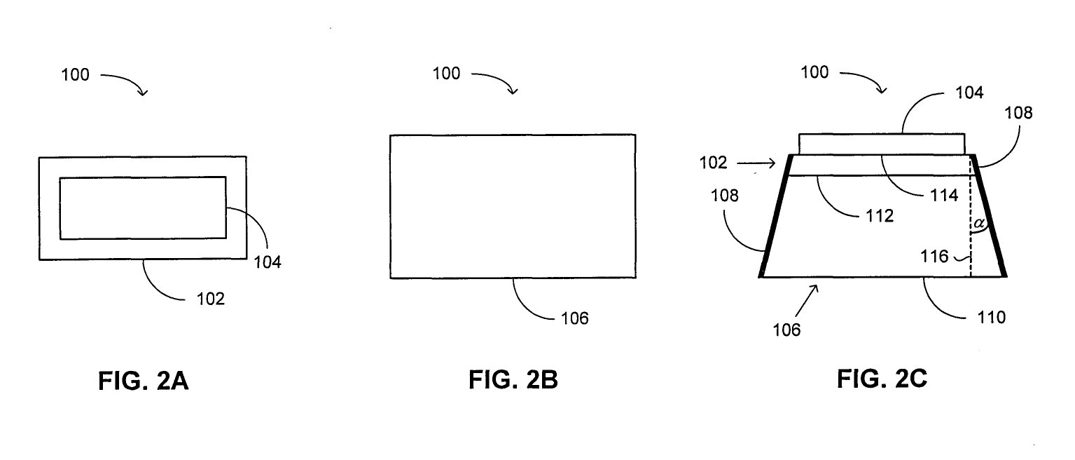

Reference is now made to FIGS. 2A, 2B and 2C. FIG. 2A is a schematic illustration of a top view of a chip-sized photovoltaic cell, generally referenced 100, constructed and operative in accordance with an embodiment of the disclosed technique. FIG. 2B is a schematic illustration of a bottom view of the chip-sized photovoltaic cell of FIG. 2A. FIG. 2C is a schematic illustration of a cross section view of the chip-sized photovoltaic cell of FIG. 2A. Photovoltaic cell 100 includes a P-type doped semiconductor (e.g., silicon) layer 102, an N-type doped semiconductor layer 106, a passivation layer 104 and a high concentration doped layer 108 (i.e., a layer having a high doping concentration, as detailed herein below).

P-type layer 102 is coupled on top of N-type layer 106, such that it covers a top surface 112 of N-type layer 106. Passivation layer 104 is coupled on a top surface 114 of P-type layer 102. The size of top surface 114 of P-type layer 102 is larger than that of the bottom surface (not shown) of passivation layer 104, such that passivation layer 104 does not fully cover top surface 114 of P-type layer 102. High concentration doped layer 108 covers the side wall surfaces of both P-type layer 102 and N-type layer 106. The size of the surface area of a bottom surface 110 of N-type layer 106 is larger than that of top surface 114 of P-type layer 102.

Chip-sized photovoltaic cell 100 is made of mono-crystalline semiconductor (e.g., silicon—produced by a Float Zone or a Czochralski process), or poly-crystalline semiconductor. The shape of the top surface of photovoltaic cell 100 is rectangular (e.g., a square or a rectangle). It is noted that, the positions of P-type layer 102 and N-type layer 106 can be interchanged. The top surface of P-type layer 102 is either smooth or textured.

Passivation layer 104 is made of silicon nitride, or silicon oxide. Passivation layer 104 provides passivation and anti-reflection protection to photovoltaic cell 100. Passivation layer 104 bonds to dangling silicon bonds (not shown) located at the surface of the silicon crystal lattice of P-type layer 102. Passivation layer 104 passivates the dangling silicon bonds, thereby lowering energy losses due to charge recombination. The refraction index of passivation layer 104 is lower than the refraction index of P-type layer 102. In this manner, the amount of light radiation, which is reflected back out of photovoltaic cell 100 through passivation layer 104, is reduced. Therefore, the efficiency of photovoltaic cell increases.

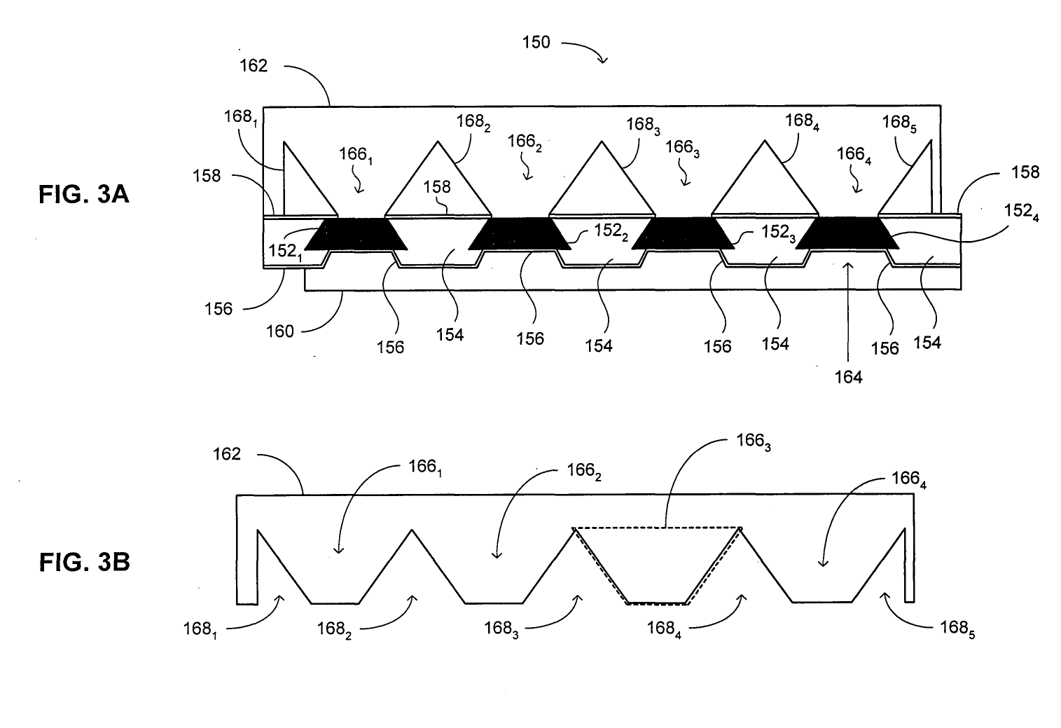

The edges (not shown) of top surface 114 of P-type layer 102 are exposed for coupling interconnects (not shown—for example, top interconnects 158 of FIG. 3A). Bottom surface 110 of N-type layer 106 is exposed. Alternatively, bottom surface 110 is covered with an aluminum layer (Al-BSF) for improving the metal contact thereof.

High concentration doped layer 108 is made of silicon oxide (i.e., substantially similar to passivation layer 104). Alternatively, high concentration doped layer 108 is made of doped semiconductor. The doping concentration of high concentration doped layer 108 is higher than the doping concentration of each of P-type layer 102 and N-type layer 106 by substantially two orders of magnitude, or more. High doping passivation layer 108 is implanted with minority carrier atoms for producing an electric field which would repel the minority carriers within the adjacent Silicon doped layer from reaching the edge. For example, in the portion of high doping layer 108 adjacent P-type layer 102, layer 108 is doped implanted with N-type ions, thus the N-type ions produce a magnetic field which repels negative charge carriers within P-type layer 102.

As detailed herein above, the surface area of the bottom surface of N-type layer 106 is larger than that of top surface 114 of P-type layer 102. High concentration doped layer 108 is tilted at an angle of a with respect to a normal 116 to top surface 114. The tilt angle a enables implanting of high concentration doped layer 108 by employing an implant doping procedure (i.e., bombarding high concentration doped layer 108 with a strong vertical ion beam).

It is noted that, the size of chip-sized photovoltaic cell 100 ranges between 0.25 to 400 millimeters square. Light radiation impinges on photovoltaic cell 100. The light radiation enters into photovoltaic cell 100 through passivation layer 104. Photovoltaic cell 100 absorbs the light radiation and generates an electric current (i.e., a P-N junction solar cell).

Reference is now made to FIGS. 3A and 3B. FIG. 3A is a schematic illustration of a cross section of a concentrating photovoltaic panel, generally referenced 150, constructed and operative in accordance with another embodiment of the disclosed technique. FIG. 3B is a schematic illustration of the optical layer of FIG. 3A. Photovoltaic panel 150 includes an array of four photovoltaic cells 152₁, 152₂, 152₃ and 152₄, an encapsulating polymer layer 154, a bottom interconnects layer 156, a top interconnects layer 158, a bottom protective layer 160 and an optical layer 162. Each of photovoltaic cells 152₁, 152₂, 152₃ and 152₄ is embedded within encapsulating layer 154. Bottom interconnects layer 156 is coupled with the bottom surfaces (not shown) of both photovoltaic cells 152₁, 152₂, 152₃ and 152₄ and of encapsulating layer 154 (i.e., bottom. interconnects layer 156 electrically interconnect the bottom surfaces of photovoltaic cells 152₁, 152₂, 152₃ and 152₄). Top interconnects layer 158 is coupled between photovoltaic cells 152₁, 152₂, 152₃ and 152₄ at the top surfaces thereof (i.e., top interconnects layer 158 electrically interconnect the top surfaces of photovoltaic cells 152₁, 152₂, 152₃ and 152₄). Encapsulating polymer layer 154 is coupled between protective layer 160 (i.e., which covers the bottom of bottom interconnects layer 156) and optical layer 162 (i.e., which covers the top of top interconnects layer 158).

Each of Photovoltaic cells 152₁, 152₂, 152₃ and 152₄ is a chip-sized photovoltaic cell, substantially similar to photovoltaic cell 100 of FIGS. 2A, 2B and 2C. Encapsulating polymer layer 154 is made of a polymer such as polyolefin-based block copolymers, and the like. Encapsulating polymer layer 154 maintains photovoltaic cells 152₁, 152₂, 152₃ and 152₄ in position and supports bottom interconnects layer 156 and top interconnects layer 158. Encapsulating layer 154 absorbs stresses arising from mismatches of thermal expansion coefficients between components of photovoltaic panel 150 (e.g., photovoltaic cells 152₁, 152₂, 152₃ and 152₄ and bottom interconnects layer 156). Encapsulating layer 154 encapsulates photovoltaic cells 152₁, 152₂, 152₃ and 152₄, which are embedded therein. In other words, encapsulating layer 154 covers all sides, and partially the bottom surface (not shown) of each of photovoltaic cells 152₁, 152₂, 152₃ and 152₄.

Bottom interconnects layer 156 is made of an electrically conductive metal, such as copper, aluminum, tungsten and the like. Alternatively, bottom interconnects layer 156 is made of an electrically conductive metal stack, such as nickel-copper and the like. As detailed herein above, bottom interconnects layer 156 is coupled with the bottom surface (not shown) of encapsulating layer 154, and with the exposed areas of the bottom surface (not shown) of photovoltaic cells 152₁, 152₂, 152₃ and 152₄. Bottom interconnects layer 156 electrically interconnects the bottom surfaces of all photovoltaic cells 152₁, 152₂, 152₃ and 152₄. Bottom interconnects layer 156 thermally interconnects photovoltaic cells 152₁, 152₂, 152₃ and 152₄ and conduct excess heat out of photovoltaic panel 150. In other words, bottom interconnects layer 156 further functions as a heat sink for photovoltaic panel 150.

Top interconnects layer 158 is made of an electrically conductive metal, such as copper, aluminum and the like. Alternatively, Top interconnects layer 158 is made of an electrically conductive metal stack, such as nickel-copper and the like. Top interconnects layer 158 is coupled with the top surface (not shown) of encapsulating layer 154, and with the exposed P-type doped semiconductor edges on the top surface of photovoltaic cells 152₁, 152₂, 152₃ and 152₄ (e.g., the edges of the top surface of P-type layer 102 of FIG. 2C). Top interconnects layer 158 electrically interconnects the top surfaces of all photovoltaic cells 152₁, 152₂, 152₃ and 152₄.

Protective layer 160 is made of a protective polymer such as Polyvinylidene Fluoride (PVDF), polymethyl methacrylate, polycarbonate and the like. Protective layer 160 covers the bottom side of photovoltaic panel 150 (i.e., bottom interconnects layer 156) and provides environmental protection thereto. One end of bottom interconnects layer 156 remains exposed such that it provides an electrical connection to an external electrical system (e.g., a power grid). In the example set forth in FIG. 3A, the left hand side end of bottom interconnects layer 156 is remains exposed, and is not covered by protective layer 160. Alternatively, a plurality of locations of bottom interconnects layer 156 are exposed, thereby providing additional electrical connections.

Optical layer 162 covers top interconnects layer 158. One end of top interconnects layer 158 is exposed, such that it provides an electrical connection to external electrical system. Alternatively, a plurality of locations of top interconnects layer 158 are exposed, thereby providing additional electrical connections. It is noted that, top interconnects layer 158 and bottom interconnects layer 156 electrically interconnect photovoltaic cells 152₁, 152₂, 152₃ and 152₄ in-parallel.

Optical layer 162 is made of optically transparent polymers having a high index of refraction such as polymethyl methacrylate, polycarbonate, and the like. Optical layer 162 includes an array of inverted truncated triangles 166₁, 166₂, 166₃ and 166₄ (i.e., CPCs 166₁, 166₂, 166₃ and 166₄). In the example set forth in FIG. 3B, CPC 166₃ is depicted as surrounded with a dotted frame for better understanding of its shape. Each of CPCs 166₁, 166₂, 166₃ and 166₄ is positioned on top of each of photovoltaic cell 152₁, 152₂, 152₃ and 152₄, respectively. The volume between CPCs 166₁, 166₂, 166₃ and 166₄ is of the shape of an array of hollow triangles 168₁, 168₂, 168₃, 168₄ and 168₅. The truncated end (i.e., the exit aperture—not shown) of each of CPCs 166₁, 166₂, 166₃ and 166₄ is positioned adjacent to the top surface of each of photovoltaic cells 152₁, 152₂, 152₃ and 152₄, respectively, and is optically coupled therewith. The refraction index of each of CPCs 166₁, 166₂, 166₃ and 166₄ is higher than that of each of hollow triangles 168₁, 168₂, 168₃, 168₄ and 168₅. In this manner, each CPC 166₁, 166₂, 166₃ and 166₄ concentrates light onto each of photovoltaic cells 152₁, 152₂, 152₃ and 152₄, respectively, by total internal reflection. Alternatively, at least a portion of array of hollow triangles 168₁, 168₂, 168₃, 168₄ and 168₅ is replaced by triangles filled with a material having refraction index lower than that of optical layer 162. Alternatively, photovoltaic panel 150 includes any number of photovoltaic cells, CPCs, and hollow triangles, such as hundred, thousand, and ten thousand photovoltaic cells and respective CPCs.

A layer of vias 164 is etched through encapsulating layer 154. The position of each via of vias layer 164 corresponds to the position of a respective one of photovoltaic cells 152₁, 152₂, 152₃ and 152₄. Each via 164 exposes (i.e., vias 164 provide openings through encapsulating layer 154, thereby exposing photovoltaic cells 152₁, 152₂, 152₃ and 152₄ out of encapsulating layer 154) a portion of the bottom surface (not shown) of the respective one of photovoltaic cells 152₁, 152₂, 152₃ and 152₄. Light radiation enters photovoltaic panel 150 through the top surface (not shown) of optical layer 162. The light is concentrated through total internal reflection by each of CPCs 166₁, 166₂, 166₃ and 166₄. The concentrated light exits optical layer 162 toward the silicon nitride passivation layer (i.e., passivation layer 104 of FIG. 2C) on the top surface of photovoltaic cells 152₁, 152₂, 152₃ and 152₄, respectively. Each of photovoltaic cells 152₁, 152₂, 152₃ and 152₄ converts the solar radiation into electrical current. Bottom interconnects layer 156 and top interconnects layer 158 conduct the electrical current from photovoltaic cells 152₁, 152₂, 152₃ and 152₄ to the electrical connections of photovoltaic panel 150. Bottom interconnects layer 156 further conducts heat away photovoltaic panel 150.

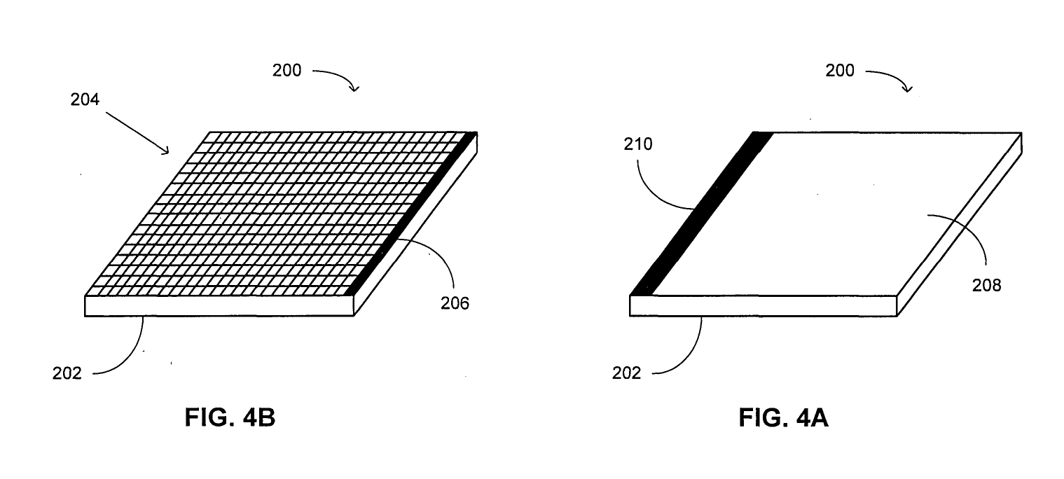

Reference is now made to FIGS. 4A and 4B which are schematic illustrations of a concentrating photovoltaic panel, generally referenced 200, constructed and operative in accordance with a further embodiment of the disclosed technique. FIG. 4A is a bottom view of concentrating photovoltaic panel 200. FIG. 4B is a schematic illustration of a top view of the photovoltaic panel 200. Photovoltaic panel 200 includes a polymer encapsulating layer 202, an optical layer 204, a peripheral top contact pad 206, a protective polymer layer 208, and a peripheral bottom contact pad 210. Optical layer 204 covers the top surface (not shown) of encapsulating polymer layer 202. Peripheral top contact pad 206 is positioned on the periphery of the top surface of is polymer layer 202, adjacent to optical layer 204. In the example set forth in FIG. 4A, contact pad 206 is positioned on the right hand side of the top surface of polymer layer 202.

Polymer encapsulating layer 202 is substantially similar to encapsulating layer 154 of FIG. 3A. Encapsulating layer 202 encapsulates a plurality of photovoltaic cells (not shown—e.g., photovoltaic cell 100 of FIGS. 2A, 2B and 2C), which are embedded therein. Optical layer 204 is substantially similar to optical layer 162 of FIG. 3A.

Optical layer 204 includes a plurality of crossed Compound Parabolic Concentrators (CPCs), substantially similar to CPCs 166₁, 166₂, 166₃ and 166₄ of FIG. 3A. A plurality of interconnects (not shown) are embedded between polymer encapsulating layer 202 and optical layer 204. Periphery contact pad 206 is made of an electrically conductive material, such as copper, aluminum, and the like. Periphery contact pad 206 provides an electrical connection for photovoltaic panel 200 (e.g., periphery top contact pad 106 connects photovoltaic panel 200 to an external system, such as an electrical power grid).

Photovoltaic panel 200 further includes a protective layer 208 and a periphery bottom contact pad 210. Protective layer 208 is positioned on the bottom surface (not shown) of encapsulating polymer layer 202. Periphery bottom contact pad 210 is positioned on the periphery of the bottom surface of encapsulating polymer layer 202, adjacent protective layer 208. In the example set forth in FIG. 4A, periphery bottom contact pad 210 is positioned on the left hand side of protective layer 208.

Protective layer 208 is substantially similar to protective layer 160 of FIG. 3A. Protective layer 208 covers the bottom side of photovoltaic panel 200 and provides environmental protection thereto. Periphery bottom contact pad 210 is made of electrically conductive is material, such as copper, aluminum and the like. Periphery bottom contact pad 210 connects photovoltaic panel 200 to an external system (e.g., an electrical power grid).

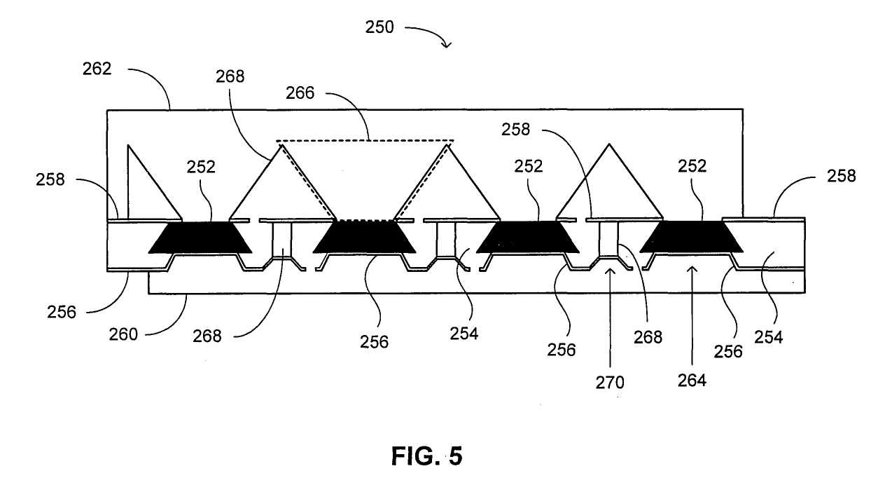

Reference is now made to FIG. 5, which is a schematic illustration of a cross section of a concentrating photovoltaic panel, generally referenced 250, constructed and operative in accordance with another embodiment of the disclosed technique. Concentrating photovoltaic panel 250 includes a plurality of photovoltaic cells 252, an encapsulating polymer layer 254, a layer of bottom interconnects 256, a layer of top interconnects 258, a protective layer 260, an optical layer 262 and an array of conductive plugs 268.

Each of photovoltaic cells 252, encapsulating layer 254, bottom interconnects layer 256, top interconnects layer 258, protective layer 260 and optical layer 262 (including CPCs 266 and triangles 268) is substantially similar to photovoltaic cells 152₁, 152₂, 152₃ and 152₄, encapsulating layer 154, bottom interconnects layer 156, top interconnects layer 158, protective layer 160 and optical layer 162 (including CPCs 152₁, 166₂, 166₃ and 166₄ and triangles 168₁, 168₂, 168₃, 168₄ and 168₅) of FIG. 3A, respectively.

Each of conductive plugs 268 is made of an electrically conductive material, such as copper, nickel, tungsten, and the like. The shape of the surface of conductive plugs 268 is rectangular (e.g., square or rectangle). Encapsulating layer 254 covers all sides of each of conductive plugs 268 (i.e., conductive plugs 268 are embedded within encapsulating layer 254).

Bottom interconnects layer 256 electrically interconnects the bottom surface (not shown) of each of photovoltaic cells 252 to an adjacent conductive plug 268. Top interconnects layer 258 electrically interconnects the top surface of each of photovoltaic cells 252 to an adjacent conductive plug 268. In the example set forth in FIG. 5, bottom interconnects layer 256 interconnects each photovoltaic cell 252 to an adjacent conductive plug 268 positioned on the right hand side of that photovoltaic cell 252. In the example set forth in FIG. 5, top interconnects layer 258 interconnects each photovoltaic cell 252 to an adjacent conductive plug 268 positioned on the left hand side of that photovoltaic cell 252. In this manner, Top interconnects layer 258 and bottom interconnects layer 256 electrically interconnect photovoltaic cells 252 in-series. Each of a plurality of vias 264 is positioned below each of photovoltaic cells 252, thereby exposing at least a portion of the bottom surface of the respective photovoltaic cell 252 (i.e., exposing out of encapsulating layer 254). Each of a plurality of vias 270 is positioned below each of conductive plugs 268, thereby exposing at least a portion of the bottom surface of the respective conductive plug 268. Alternatively, at least a first portion of the photovoltaic cells (e.g., cells 152₁, 152₂, 152₃ and 152₄ and 252 of FIGS. 3A and 5, respectively) included in the concentrated photovoltaic panel (e.g., panel 200 of FIGS. 4A and 4B) are interconnected in-parallel, and at least another portion of the photovoltaic cells are interconnected in-series.

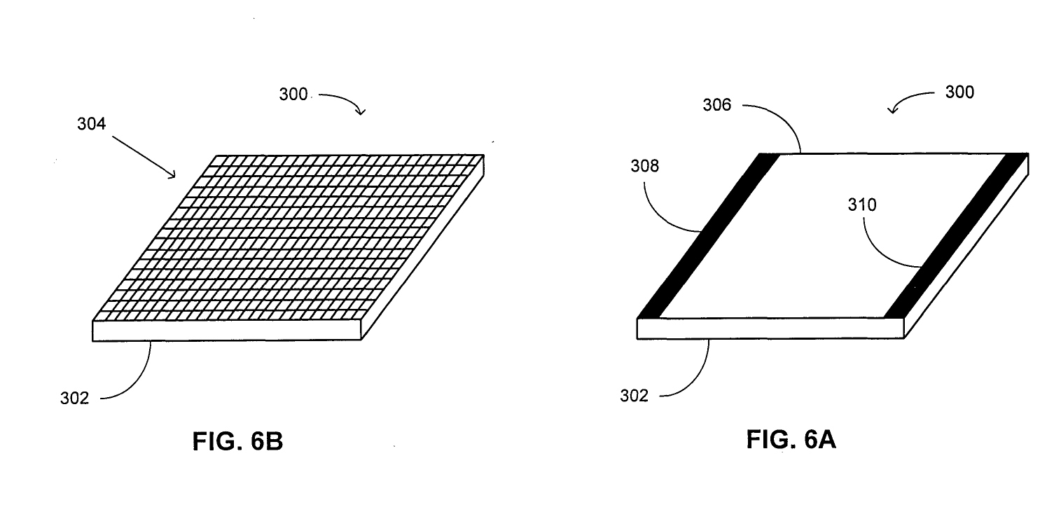

Reference is now made to FIGS. 6A and 6B. FIG. 6A is a schematic illustration of a bottom view of a concentrating photovoltaic panel, generally referenced 300, constructed and operative in accordance with a further embodiment of the disclosed technique. FIG. 6B is a schematic illustration of a top view of the photovoltaic panel of FIG. 6A. Photovoltaic panel 300 includes an encapsulating polymer layer 302, an optical layer 304, a protective layer 306, a first bottom contact pad 308 and a second bottom contact pad 310. Encapsulating layer 302 is coupled between optical layer 304 and protective layer 306. First contact pad 308 is coupled on the bottom surface of encapsulating layer 302 adjacent protective layer 306 (i.e., on a first hand side of protective layer). Second contact pad 310 is coupled on the bottom surface of encapsulating layer 302 adjacent protective layer 306, opposite to first contact pad 308 (i.e., on a second hand side of protective layer, opposite to the first hand side).

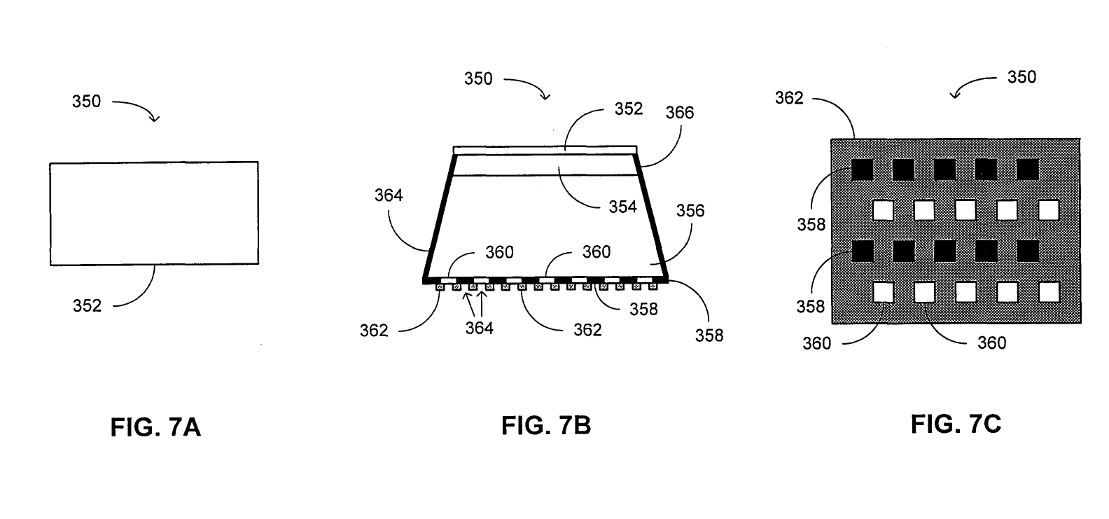

Each of encapsulating polymer layer 302, optical layer 304 and protective layer 306 is substantially similar to encapsulating polymer layer 154, optical layer 162 and protective layer 160 of FIG. 3A, respectively. Encapsulating layer 302 includes a plurality of photovoltaic cells (not shown) substantially similar to photovoltaic cell 350 of FIGS. 7A, 7B and 7C (i.e., rear contact cell). Optical layer 304 includes a plurality of crossed CPCs (not shown) substantially similar to CPCs 166₁, 166₂, 166₃ and 166₄ of FIG. 3A. Each of first contact pad 308 and second contact pad 310 is substantially similar to bottom contact pad 210 of FIG. 4A.

Reference is now made to FIGS. 7A, 7B and 7C. FIG. 7A is a schematic illustration of a top view of a chip-sized photovoltaic cell, generally referenced 350, constructed and operative in accordance with another embodiment of the disclosed technique. FIG. 7B is a cross section view of the photovoltaic cell of FIG. 7A. FIG. 7C is a bottom view of the photovoltaic cell of FIG. 7A. Photovoltaic cell 350 includes a first passivation layer 352, a first N-type doped silicon layer 354 (i.e., N-type layer—emitter layer 354), a first P-type doped silicon layer 356 (i.e., P-type layer—base layer 356), a second P-type layer 358, a second N-type layer 360, a second passivation layer 362 and high concentration doped layer 366.

First passivation layer 352 covers the top surface (not shown) of emitter layer 354. Emitter layer 354 covers the top surface of base layer 356. The surface area of the top surface of emitter layer 354 is smaller than the surface area of the bottom surface (not shown) of base layer 356. Second P-type layer 358 and second N-type layer 360 are integrated such that they form a checkered pattern layer (not shown). The checkered pattern layer of second. P-type layer 358 and second N-type layer 360 is coupled with the bottom surface of base layer 356. Second passivation layer 362 covers the bottom surface (not shown) of the checkered pattern layer of second P-type layer 358 and second N-type layer 360. High concentration doped layer 366 covers all side surfaces (not shown) of photovoltaic cell 350.

Photovoltaic cell 350 is a rear contact solar cell (i.e., the electrical connections thereof are positioned on the bottom thereof). Photovoltaic cell 350 is made of mono-crystalline silicon (i.e., produced by a Float Zone or a Czochralski process). The shape of the top surface (not shown) of photovoltaic cell 350 (i.e., of first passivation layer 352) is rectangular (e.g., a square or a rectangle).

Each of first passivation layer 352, emitter layer 354, base layer 356 and High concentration doped layer 366 is substantially similar to passivation layer 104, P-type doped silicon layer 102, N-type doped silicon layer 106 and high concentration doped layer 108 of FIGS. 2A, 2B and 2C, respectively.

Second passivation layer 362 is a passivation layer made of silicon oxide or polyimide. Second passivation layer 362 prevents electrical shorts (i.e., second passivation layer 362 is an electrical insulation layer). Second passivation layer 362 covers the checkered pattern layer of second P-type layer 358 and second N-type layer 360. Second passivation layer 362 includes a plurality of openings 364 over the checkered pattern layer of second P-type layer 358 and second N-type layer 360. Openings 364 define the electrical contact areas for second P-type layer 358 and second N-type layer 360 (i.e., rear contact photovoltaic cell).

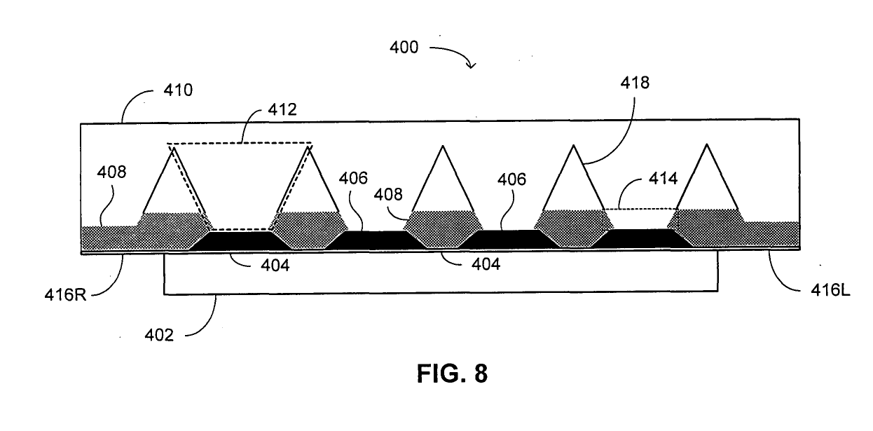

Reference is made to FIG. 8, which is a schematic illustration of a cross section of a concentrating photovoltaic panel, generally referenced 400, constructed and operative in accordance with a further embodiment of the disclosed technique. Photovoltaic panel 400 includes a protective layer 402, an interconnects layer 404, an array of photovoltaic cells 406, an encapsulating layer 408 and an optical layer 410. Optical layer 410 includes a plurality of CPCs 412 and a plurality of empty triangles 418. Protective layer 402 covers the bottom surface of interconnects layer 404, except for the two side ends 416R and 416L, thereof. Encapsulating layer 408 encapsulates each of photovoltaic cells 406 (i.e., photovoltaic cells 406 are embedded within encapsulating layer 408). Interconnects layer is coupled with the bottom surface (not shown) of encapsulating layer 408 and of photovoltaic cells 406. Optical layer 410 covers the top surfaces (not shown) of encapsulating layer 408 and of photovoltaic cells 406, such that each of photovoltaic cells 406 is optically coupled with the exit aperture (the truncated end—not shown) of a respective one of CPCs 412.

Each of protective layer 402, interconnects layer 404 photovoltaic cells 406, encapsulating layer 408, optical layer 410, CPCs 412 and empty triangles 418, is substantially similar to each of protective layer 160, interconnects layer 156, photovoltaic cells 152₁, 152₂, 152₃ and 152₄, encapsulating layer 154, optical layer 162, CPCs 166₁, 166₂, 166₃ and 166₄ and triangles 168₁, 168₂, 168₃, 168₄ and 168₅ of FIG. 3A, respectively.

A plurality of vias 414 are defined in the space above each of photovoltaic cells 406, such that each of vias 414 exposes a portion of the top surface of a selected one of photovoltaic cells 406 (i.e., exposes out of encapsulating layer 408). As detailed above protective layer 402 partially covers interconnects layer 404, except for side ends 416R and 416L, thereof. Exposed side ends 416R and 416L of interconnects layer 404 provides two electrical connections to an external electrical system.

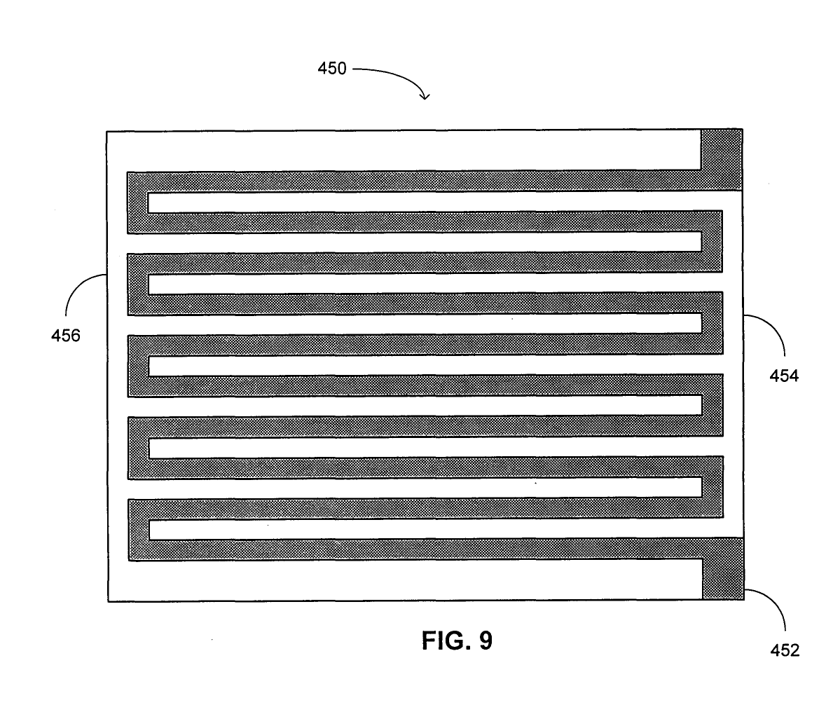

Reference is now made to FIG. 9, which is a schematic illustration of a bottom view of an interconnect of a photovoltaic cell, generally referenced 450, constructed and operative in accordance with another embodiment of the disclosed technique. Interconnect 450 electrically interconnects a P-type layer and an N-type layer of a photovoltaic cell (e.g., second P-type layer 358 and second N-type layer 360 of photovoltaic cell 350 of FIGS. 7A, 7B and 7C). Interconnect 450 includes a passivation layer 452, an N-type interconnect 454 and a P-type interconnect 456. Passivation layer 452 covers the bottom surfaces of N-type interconnect 454 and P-type interconnect 456. N-type interconnect 454 is in the shape of a plurality of perpendicular elongated strips (not shown), which are interconnected on a first side end (e.g., right side end) of interconnect 450. P-type interconnect 456 is in the shape of a plurality of interconnected perpendicular elongated strips (not shown), which are interconnected on a second side end (e.g., left side end) of interconnect 450.

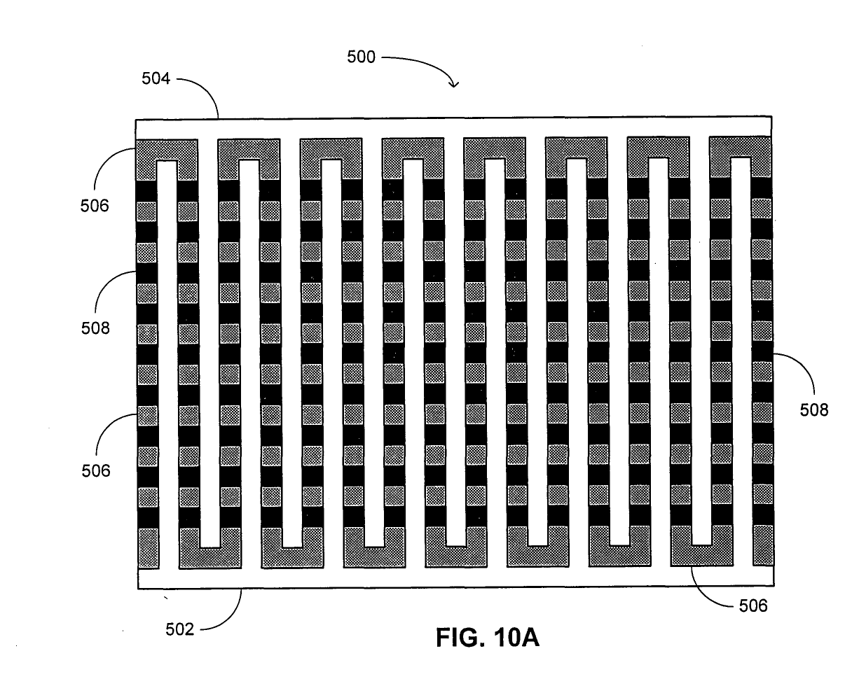

Passivation layer 452 is substantially similar to passivation layer 362 of FIGS. 7B and 7C. Each of N-type interconnect 454 and P-type interconnect 456 electrically interconnects second N-type layer 360 and second P-type layer 358 of FIGS. 7B and 7C, respectively. It is noted that interconnect 450 is a portion of a photovoltaic panel metallization platform and not a portion of the photovoltaic cell. For example, interconnect 450 is a portion of interconnect platform 500 of FIG. 10 and not a portion of photovoltaic cell 350.

Reference is now made to FIGS. 10A and 10B. FIG. 10A is a schematic illustration of a bottom view of an interconnects platform, generally referenced 500, of a photovoltaic panel, constructed and operative in accordance with a further embodiment of the disclosed technique. FIG. 10B is an enlarged view of a segment of FIG. 10A. Interconnects platform 500 electrically interconnects photovoltaic cells within a photovoltaic panel (e.g., photovoltaic panel 400 of FIG. 8). Interconnects platform 500 includes an N-type interconnects layer 502, a P-type interconnects layer 504, a bottom surface of an encapsulating layer 506 and a bottom surface of a photovoltaic array 508.

Bottom surface of encapsulating layer 506 is the bottom surface of an encapsulating layer, such as the bottom surface of encapsulating layer 408 of FIG. 8. Bottom surface of a photovoltaic array 508 is a bottom surface of a photovoltaic cell array, such as array of photovoltaic cells 406 of FIG. 8. Each of N-type interconnects layer 502 and P-type interconnects layer 504 is substantially similar to interconnects layer 404 of FIG. 8. N-type interconnects layer 502 partially covers encapsulating layer 506, and electrically interconnects all photovoltaic cells 508 by their N-type outputs. N-type interconnects layer 502 forms a plurality of perpendicular elongated strips, which are interconnected on a first side end (e.g., bottom side end) of interconnects platform 500. N-type interconnects layer 502 provides an electrical contact to an external electrical system.

P-type interconnects layer 504 partially covers encapsulating layer 506, and electrically interconnects all photovoltaic cells 508 by their P-type outputs. P-type interconnects layer 504 forms a plurality of perpendicular elongated strips, which are interconnected on a second side end (e.g., top side end) of interconnects platform 500. P-type interconnects layer 504 provides an electrical contact to an external electrical system. N-type interconnects layer 502 and P-type interconnects layer 504 electrically interconnect photovoltaic cells 508 in-parallel.

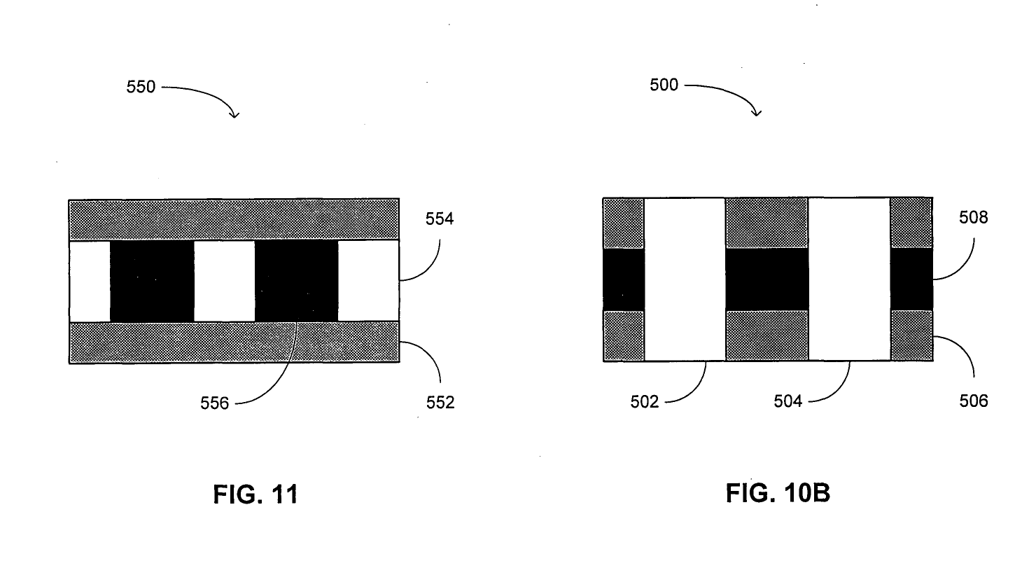

Reference is now made to FIG. 11, which is a schematic illustration of a bottom view of an interconnects platform, generally referenced 550, of a photovoltaic panel, constructed and operative in accordance with another embodiment of the disclosed technique. Interconnects platform 550 includes a bottom surface of an encapsulating layer 552, an interconnect layer 554 and a bottom surface of photovoltaic cells array 556. Bottom surface of an encapsulating layer 552 is a bottom surface of an encapsulating layer, such as encapsulating layer 408 of FIG. 8. Bottom surface of photovoltaic cells array 556 is a bottom surface of an array of photovoltaic cells, such as photovoltaic cells array 406 of FIG. 8. Interconnect layer 554 is substantially similar to interconnects layer 404 of FIG. 8. Interconnect layer 554 electrically interconnects all photovoltaic cells 556 by their N-type and by their P-type outputs. Interconnect layer 554 electrically interconnects photovoltaic cells 556 in-series. In accordance with another embodiment of the disclosed technique, part of the photovoltaic cells included of the concentrated photovoltaic panel, are interconnected in-parallel, and another part of the photovoltaic cells are interconnected in-series.

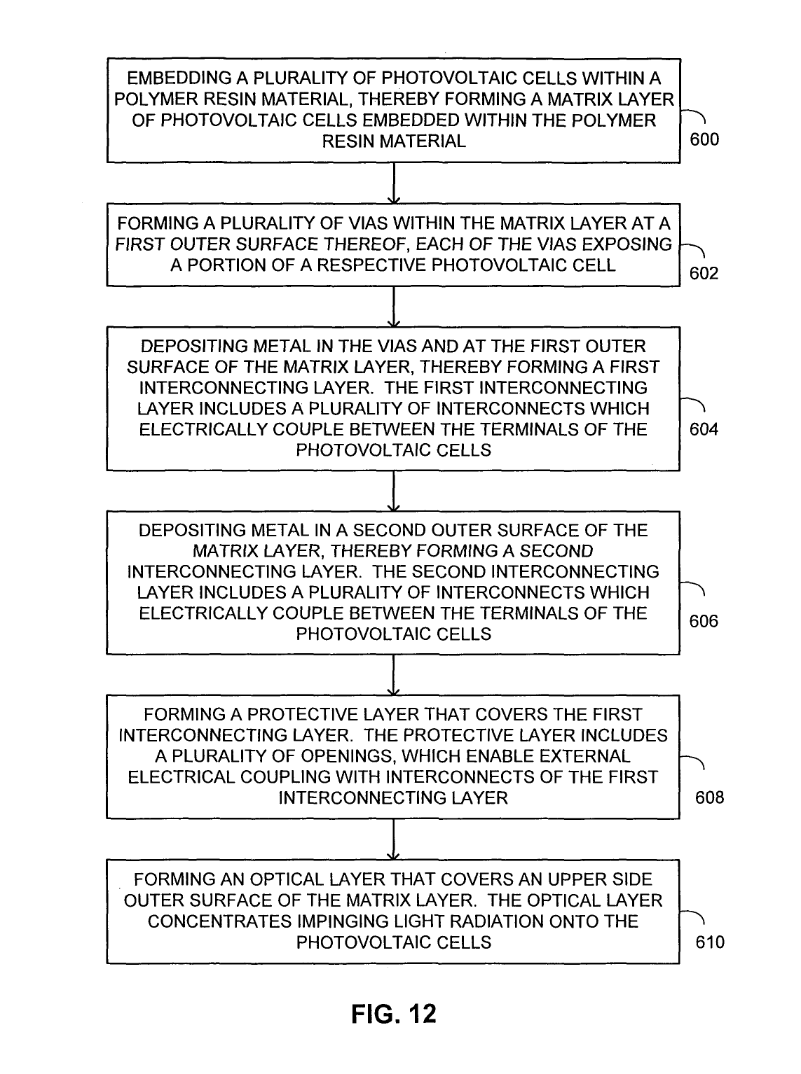

Reference is now made to FIG. 12, which is a schematic illustration of a block diagram of a method for constructing a concentrating photovoltaic panel, operative in accordance with a further embodiment of the disclosed technique. In procedure 600, a plurality of photovoltaic cells are encapsulated within a polymer resin material, thereby forming a matrix layer of photovoltaic cells embedded within the polymer resin material. With reference to FIG. 3A, photovoltaic cells 152₁, 152₂, 152₃ and 152₄ are embedded within layer 154, whereby layer 154 covers all sides of each of photovoltaic cells 152₁, 152₂, 152₃ and 152₄ (i.e., encapsulating layer and embedded photovoltaic cells 152₁, 152₂, 152₃ and 152₄ form a matrix layer).

In procedure 602, a plurality of vias are formed within the matrix layer at a first outer surface thereof, each of the vias exposing a portion of a respective photovoltaic cell out of the encapsulating matrix. With reference to FIG. 3A, each of vias 164 exposes a respective one of photovoltaic cells 152₁, 152₂, 152₃ and 152₄ out of encapsulating layer 154.

In procedure 604, metal is deposited in the vias and at the first outer surface of the matrix layer, thereby forming a first interconnecting layer. The first interconnecting layer includes a plurality of interconnects which electrically couple between the terminals of the photovoltaic cells. With reference to FIG. 3A, bottom interconnects layer 156 is formed on the underside of layer 154, and on the underside of photovoltaic cells 152₁, 152₂, 152₃ and 152₄ through vias 164. Bottom interconnects layer 156 electrically couples between photovoltaic cells 152₁, 152₂, 152₃ and 152₄.

In procedure 606, metal is deposited in a second outer surface of the matrix layer, thereby forming a second interconnecting layer. The second interconnecting layer includes a plurality of interconnects which electrically couple between the terminals of the photovoltaic cells. With reference to FIG. 3A, top interconnects layer 158 is formed on the upper side of layer 154. Top interconnects layer 158 electrically couples between photovoltaic cells 152₁, 152₂, 152₃ and 152₄.

In procedure 608, a protective layer that covers the first interconnecting layer is formed. The protective layer includes a plurality of openings, which enable external electrical coupling with interconnects of the first interconnecting layer. With reference to FIG. 3A, protective layer 160 covers bottom interconnecting layer 156. At least at one edge of bottom interconnecting layer 156 is exposed, thereby enabling external electrical coupling.

In procedure 610, an optical layer that covers an upper side outer surface of the matrix layer is formed. The optical layer concentrates impinging light radiation onto the photovoltaic cells With reference to FIG. 3A, Optical layer 162 covers layer encapsulating layer 154. Optical layer 162 includes a plurality of crossed compound parabolic concentrators 166₁, 166₂, 166₃ and 166₄ which are optically coupled with photovoltaic cells 152₁, 152₂, 152₃ and 152₄, respectively. Each of CPCs 166₁, 166₂, 166₃ and 166₄ concentrate light radiation onto each of photovoltaic cells 152₁, 152₂, 152₃ and 152₄, respectively.

1. A concentrating photovoltaic panel comprising:
an encapsulating polymer layer;
an array of photovoltaic cells, each of said photovoltaic cells being embedded within said encapsulating layer;
a plurality of first interconnects being coupled with each of said photovoltaic cells and with said encapsulating layer, said plurality of first interconnects electrically interconnecting all said photovoltaic cells of said array there-between; and
an optical layer coupled on top of said encapsulating layer and said array of photovoltaic cells, said optical layer concentrating light radiation onto said array of photovoltaic cells;
wherein at least one of said first interconnects remains exposed out of said protective layer.

2. The photovoltaic panel of claim 1, further comprising a bottom protective layer coupled below said encapsulating layer and said array oh photovoltaic cells, said protective layer is made of a protective polymer, said protective layer providing environmental protection to said photovoltaic panel.

3. The photovoltaic panel of claim 1, wherein said optical layer includes a plurality of crossed compound parabolic concentrators, each of said parabolic concentrators is optically coupled with a respective one of said array of photovoltaic cells, each of said parabolic concentrators concentrating light radiation onto said respective photovoltaic cell by total internal reflection.

4. The photovoltaic panel of claim 3, wherein said optical layer and said parabolic concentrators are made of an optically transparent polymer having a high index of refraction.

5. The photovoltaic panel of claim 1, further comprising a plurality of second interconnects being coupled with each of said photovoltaic cells and with said encapsulating layer, said plurality of second interconnects electrically interconnect all said photovoltaic cells of said array there-between, wherein at least one of said second interconnects remains exposed out of said optical layer.

6. The photovoltaic panel of claim 5, wherein said plurality of first interconnects and said plurality of second interconnects electrically interconnect said array of photovoltaic cells in parallel.

7. The photovoltaic panel of claim 1, wherein said encapsulating layer is made of polyolefin-based block copolymers.

8. The photovoltaic panel of claim 1, wherein said encapsulating layer is made of polycarbonate.

9. The photovoltaic panel of claim 1, wherein each of said plurality of first interconnects is made of a conductive material selected from the list consisting of:
copper;
aluminum;
tungsten; and
nickel-copper.

10. The photovoltaic panel of claim 1, wherein said protective layer is made of a protective polymer selected from the list consisting of:
Polyvinylidene Fluoride (PVDF);
polymethyl methacrylate; and
polycarbonate.

11. The photovoltaic panel of claim 1, further comprising a plurality of vias within said encapsulating layer, each of said vias exposing a portion of the bottom surface of each of said photovoltaic cells.

12. The photovoltaic panel of claim 5, further comprising a plurality of conductive plugs embedded within said encapsulating layer, each of said conductive plugs is coupled with a first adjacent photovoltaic cell of said array by a first interconnect of said plurality of first interconnects, and to a second adjacent photovoltaic cell of said array by a second interconnect of said plurality of second interconnects.

13. The photovoltaic panel of claim 12, wherein said first plurality of interconnects, said second plurality of second interconnects and said plurality of conductive plugs couple said array of photovoltaic cells in series.

14. The photovoltaic panel of claim 12, wherein said first plurality of interconnects, said second plurality of second interconnects and said plurality of conductive plugs couple at least a portion of said array of photovoltaic cells in series and at least another portion of said array of photovoltaic cells in parallel.

15. The photovoltaic panel of claim 1, wherein the size of each of said photovoltaic cells ranges between 0.25 to 400 millimeters square.

16. A method for producing a photovoltaic concentrating panel, the method comprising the procedures of:
forming a matrix layer of photovoltaic cells embedded within a polymer resin material;
forming a first interconnecting layer, said first interconnecting layer including a plurality of interconnects which electrically couple between terminals of said photovoltaic cells;
forming a protective layer that covers said first interconnecting layer, said protective layer includes at least one opening, enabling external electrical coupling with interconnects of said first interconnecting layer; and
forming an optical layer that covers an upper side outer surface of said matrix layer, said optical layer including a plurality of cross compound parabolic concentrators, each of said parabolic concentrators being optically coupled with a respective one of said plurality of photovoltaic cells.

17. The method of claim 16, further comprising the procedure of forming a plurality of vias at a first outer surface of said matrix layer, each of said vias exposing a portion of a respective photovoltaic cell.

18. The method of claim 16, wherein said procedure of forming said first interconnecting layer is performed by depositing metal in said vias and at said first outer surface of said matrix layer.

19. The method of claim 16, further comprising the procedure of depositing metal in a second outer surface of the matrix layer and at the side ends of either a first outer surface or said second outer surface of said photovoltaic cells, thereby forming a second interconnecting layer, said second interconnecting layer including a plurality of interconnects which electrically couple between terminals of said photovoltaic cells.

20. A photovoltaic cell comprising:
an N-type doped semiconductor layer;
a P-type doped semiconductor layer positioned on the top surface of said N-type layer, the size of the surface area of the bottom surface of said N-type layer is larger than that of said top surface of said P-type layer;
a passivation layer positioned on said top surface of said P-type layer, said passivation layer providing passivation protection to said photovoltaic cell; and
a high concentration doped layer covering all sides of said P-type layer and of said N-type layer, the doping concentration of said high concentration doped layer is larger than that of each of said P-type layer and said N-type layer by at least two orders of magnitude, said high concentration doped layer is tilted with respect to the normal to said top surface of said P-type layer.

21. The photovoltaic cell of claim 20, wherein the size of the top surface of said P-type layer is larger than that of the bottom surface of said passivation layer, such that said passivation layer does not fully cover the top surface of said P-type layer.

22. The photovoltaic cell of claim 20, wherein the position of said N-type layer and said P-type layer is interchanged there-between, such that said N-type layer is coupled on top of said P-type layer, and such that the size of the surface area of the bottom surface of said P-type layer is larger than that of said top surface of said N-type layer.

23. The photovoltaic cell of claim 20, wherein said high concentration doped layer is replaced with a silicon oxide layer.
